(19) United States
(12) Patent Application Publication
(10) Pub. No.: US 2022/0246789 A1
(43) Pub. Date: Aug. 4, 2022

(54) SEMICONDUCTOR DEVICE AND METHOD FOR PRODUCING SEMICONDUCTOR DEVICE

(71) Applicants: TOYODA GOSEI CO., LTD., Kiyosu-shi (JP); MEIJO UNIVERSITY, Nagoya-shi (JP); KOITO MANUFACTURING CO., LTD., Tokyo (JP)

(72) Inventors: Koji OKUNO, Kiyosu-shi (JP); Koichi MIZUTANI, Kiyosu-shi (JP); Masaki OYA, Kiyosu-shi (JP); Kazuyoshi IIDA, Kiyosu-shi (JP); Naoki SONE, Shizuoka-shi (JP); Satoshi KAMIYAMA, Nagoya-shi (JP); Tetsuya TAKEUCHI, Nagoya-shi (JP); Motoaki IWAYA, Nagoya-shi (JP); Isamu AKASAKI, Nagoya-shi (JP)

(21) Appl. No.: 17/587,397

(22) Filed: Jan. 28, 2022

(30) Foreign Application Priority Data
Feb. 1, 2021 (JP) 2021-014662

(51) Int. Cl. H01L 33/00; H01L 33/38

(52) U.S. Cl. CPC H01L 33/005; H01L 33/0008; H01L 33/387

(57) ABSTRACT

A buried layer forming step includes three steps of a facet structure forming step, a c-plane forming step, and a flattening step. In the facet structure forming step, a buried layer grows to form a periodic facet structure that matches an arrangement pattern of columnar semiconductors. In the c-plane forming step, the buried layer grows such that a {0001} plane (upper surface) is formed in a region of the buried layer corresponding to an upper portion of the columnar semiconductor. In the flattening step, lateral growth of the buried layer is promoted and the c-plane formed in the c-plane forming step is widened to flatten a surface of the buried layer.

### CROSS-REFERENCE TO RELATED APPLICATIONS

The present application claims the benefit of priority of Japanese Patent Application No. 2021-014662, filed on Feb. 1, 2021, the disclosure of which is incorporated herein by reference.

### TECHNICAL FIELD

The technical field of the present specification relates to a semiconductor device and a method for producing the semiconductor device.

### BACKGROUND

The semiconductor light-emitting device emits light by recombination of holes and electrons in an active layer. Commonly, a flat sheet-shaped structure has been used as an active layer. In recent years, active layers having a three-dimensional structure such as a columnar structure have been studied.

For example, JP-A-2020-77817, JP-A-2019-12744, and JP-A-2019-169735 disclose a semiconductor light emitting device having a core-shell type structure (multi-quantum cell; MQS). The core-shell type structure includes a semiconductor layer that is a hexagonal columnar nanowire (NW), and an active layer that is formed to cover the hexagonal columnar structure. In MQS, a main surface of the active layer can be an m-plane. In the case of the m-plane, polarization does not occur, and there is no quantum confinement Stark effect, so that an improvement in internal quantum efficiency can be expected.

### SUMMARY

In a semiconductor device having a nanowire structure, it is necessary to bury a space between the nanowires with a semiconductor with no a gap and flatten the space. When the semiconductor grows at a high temperature, it is possible to bury flatly. However, the active layer is thermally damaged. In contrast, when the growth temperature is lowered in order to avoid thermal damage, voids (spaces) are formed in the buried layer, or large pits are formed on the surface, resulting in a very rough surface.

An object of the present disclosure is to provide a method for producing a semiconductor device including a plurality of columnar semiconductors that are arranged periodically, and a buried layer that is buried between the columnar semiconductors, by which thermal damage to the columnar semiconductors can be prevented, and voids and surface roughness of the buried layer can be prevented.

A method for producing a semiconductor device according to the present disclosure is a method for producing a semiconductor device including a plurality of columnar semiconductors that are arranged periodically and a buried layer that is buried between the columnar semiconductors. A step of forming the buried layer includes a facet structure forming step of causing a buried layer to grow to form a periodic facet structure that matches an arrangement pattern of the columnar semiconductors, and a flattening step of flattening the buried layer by causing the buried layer to grow in a lateral direction by means of causing the buried layer to grow at a temperature higher than that in the facet structure forming step.

In the method for producing a semiconductor device according to the present disclosure, a growth temperature of the buried layer in the facet structure forming step may be 900 to 950° C., and a growth temperature of the buried layer in the flattening step may be 1000 to 1100° C.

The method for producing a semiconductor device according to the present disclosure may further include, after the facet structure forming step and before the flattening step, a c-plane forming step of forming a {0001} plane in a region of the buried layer corresponding to an upper portion of the columnar semiconductor by causing the buried layer to grow at a temperature higher than that in the facet structure forming step and lower than that in the flattening step.

In the method for producing a semiconductor device according to the present disclosure, a growth temperature of the buried layer in the c-plane forming step may be 950 to 1050° C.

In the method for producing a semiconductor device according to the present disclosure, in the facet structure, a proportion of an area of the {0001} plane of the buried layer to a total area of the surface of the buried layer when the surface of the buried layer is projected onto the {0001} plane is 30% or less.

In the method for producing a semiconductor device according to the present disclosure, in the step of forming the buried layer, a growth pressure of the buried layer may be 10 to 100 kPa, V/III may be 1000 to 5000, and a growth rate may be 5 to 50 nm/min.

In the method for producing a semiconductor device according to the present disclosure, the columnar semiconductors are arranged in a square lattice shape or a regular triangular lattice shape, H is a height of the columnar semiconductors, L is a distance between the columnar semiconductors, and H and L are set to satisfy 1.06×H−0.25≤L≤1.06×H+2.

In addition, the semiconductor device of the present disclosure is a semiconductor device including a plurality of columnar semiconductors that are periodically arranged and a buried layer that is buried between the columnar semiconductors. On the surface of the buried layer, threading dislocations are distributed with the same periodicity as arrangement of the columnar semiconductors, and a dislocation density in an upper region of the columnar semiconductors is different from a dislocation density in another region.

The present specification provides a method for producing a semiconductor device, by which voids and surface roughness of a buried layer can be prevented while preventing thermal damage to a columnar semiconductor.

### BRIEF DESCRIPTION OF DRAWINGS

FIG. 1 is a perspective view showing a schematic configuration of a semiconductor light-emitting device 100 according to a first embodiment.

FIG. 2 is a cross-sectional view of the semiconductor light-emitting device 100 according to the first embodiment.

FIG. 3 is a diagram of a schematic configuration of a columnar semiconductor 130.

FIG. 4 is a cross-sectional view taken along a line IV-IV in FIG. 3.

FIG. 5 is a diagram showing an arrangement of the columnar semiconductors 130.

FIG. 6 is a view for illustrating a method for producing the semiconductor light-emitting device according to the first embodiment.

FIG. 7 is a view for illustrating the method for producing the semiconductor light-emitting device according to the first embodiment.

FIG. 8 is a view for illustrating the method for producing the semiconductor light-emitting device according to the first embodiment.

FIG. 9 is a view for illustrating the method for producing the semiconductor light-emitting device according to the first embodiment.

FIG. 10 is a view for illustrating the method for producing the semiconductor light-emitting device according to the first embodiment.

FIG. 11 is a view for illustrating the method for producing the semiconductor light emitting device according to the first embodiment.

FIG. 12 is a view for illustrating the method for producing the semiconductor light emitting device according to the first embodiment.

FIG. 13 is a view for illustrating the method for producing the semiconductor light-emitting device according to the first embodiment.

FIGS. 14A to 14F are SEM images of a buried layer 140.

FIGS. 15A to 15F are SEM images of the buried layer 140.

FIG. 16 is a CL image obtained by imaging a surface of the buried layer 140.

### DESCRIPTION OF EMBODIMENTS

Hereinafter, a specific embodiment will be described with reference to the drawings by taking a semiconductor light emitting device as an example. However, the technique of the present specification is not limited to the embodiment. A laminated structure and an electrode structure of layers of the semiconductor light emitting device described later are exemplified. In some cases, a laminated structure different from that of the embodiment may be used. The ratio of thicknesses of layers in each figure is conceptually shown, and the ratio of the actual thicknesses is not indicated.

### (First Embodiment) 1. Semiconductor Light Emitting Device

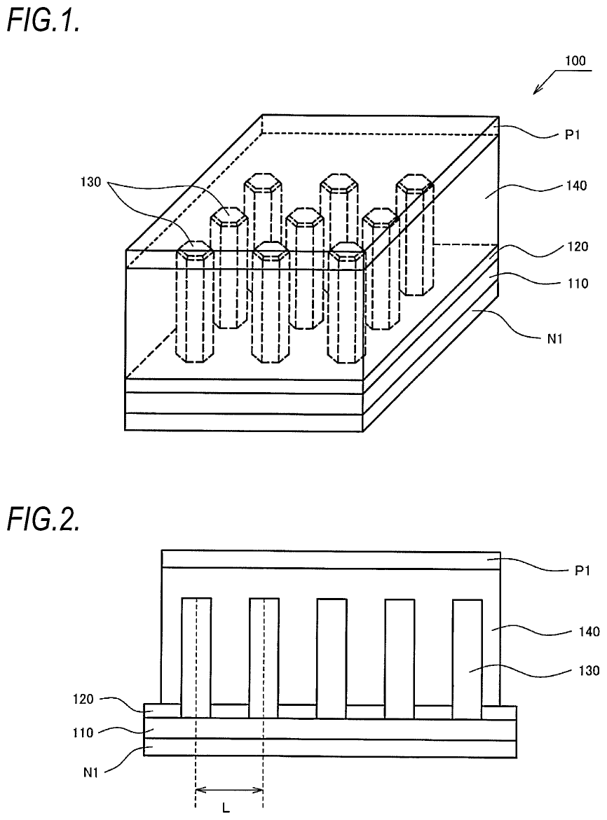

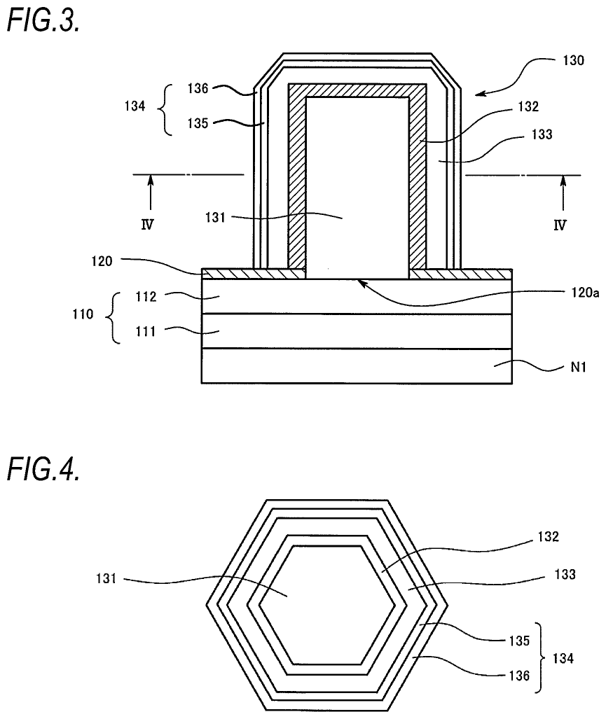

FIG. 1 is a perspective view showing a schematic configuration of a semiconductor light emitting device 100 according to a first embodiment. FIG. 2 is a cross-sectional view of the semiconductor light emitting device 100. As shown in FIGS. 1 and 2, the semiconductor light emitting device 100 includes a substrate 110, a mask 120, columnar semiconductors 130, a buried layer 140, a cathode electrode N1, and an anode electrode P1. FIG. 3 is a diagram showing a configuration of the columnar semiconductor 130.

The substrate 110 is a growth substrate for supporting the mask 120, the columnar semiconductors 130, and the buried layer 140. The substrate 110 includes a conductive substrate 111 and an n-type semiconductor layer 112. The conductive substrate 111 is, for example, an n-type GaN substrate having a c-plane as a main surface, Si, or SiC. The n-type semiconductor layer 112 is, for example, an n-type GaN layer. These configurations are merely examples, and structures other than those described above may be employed.

The mask 120 is a material that inhibits the growth of a semiconductor on a surface. As will be described later, a through-hole is formed in the mask 120. The mask 120 may be a transparent insulating film. In this case, the mask 120 hardly absorbs light. The current suitably flows through the columnar semiconductors 130 without passing through the mask 120. Examples of the material of the mask 120 include SiO₂, SiNₓ, and Al₂O₃.

As shown in FIGS. 1 and 2, the columnar semiconductors 130 are a columnar group III nitride semiconductor. The columnar semiconductors 130 are formed on the substrate 110. More specifically, the columnar semiconductor 130 is a semiconductor selectively growing from a surface of the substrate 110 exposed to an opening 120a of the mask 120. The columnar semiconductors 130 have a hexagonal columnar shape. A cross section of the columnar semiconductor 130 perpendicular to the central axis direction is a regular hexagon or a flat hexagon. The columnar semiconductors 130 are arranged in a square lattice shape. In addition to the square lattice shape, a periodic arrangement such as a parallel body lattice, a rectangular lattice, a rhombic lattice, a regular triangular lattice, or a honeycomb shape may be used.

The columnar semiconductors 130 are preferably arranged along a crystal orientation of the n-type semiconductor layer 112. For example, in a case where the columnar semiconductors 130 are arranged in a triangular lattice on the {0001} plane of a group III nitride semiconductor having a wurtzite structure, the columnar semiconductors 130 are preferably arranged in a relationship in which the triangular lattice overlaps an optional crystal orientation of the group III nitride semiconductor or is rotated by 30°. On the other hand, in a case where the columnar semiconductors 130 are arranged in a square lattice, the arrangement is two-fold symmetric and is different from the symmetry of the {0001} plane of the group III nitride semiconductor. In this case, one side of the square lattice is preferably aligned with an optional crystal orientation of the group III nitride semiconductor. The arrangement of the columnar semiconductors 130 is aligned with the crystal orientation of the n-type semiconductor layer 112 in this manner, and thereby, a growth mode of the buried layer 140 tends to be stable, and the buried layer 140 tends to be easily buried. Of course, the arrangement of the columnar semiconductors 130 may be deviated from or completely different from the crystal orientation of the n-type semiconductor layer.

The buried layer 140 is a layer for burying a gap between one columnar semiconductor 130 and another one columnar semiconductor 130. The buried layer 140 covers the columnar semiconductors 130. A surface of the buried layer 140 is flat. A material of the buried layer 140 is, for example, Si-doped n-GaN. The buried layer 140 is provided, and thereby, a light extraction rate is improved.

The cathode electrode N1 is formed on a back surface of the substrate 110 (the surface opposite to the side on which the mask 120 is provided).

The anode electrode P1 is formed on the buried layer 140.

### 2. Columnar Semiconductor

As shown in FIG. 3, the columnar semiconductor 130 includes a columnar n-type semiconductor 131, an active layer 132, a tubular p-type semiconductor 133, and a tunnel junction layer 134. A side surface of the columnar n-type semiconductor 131 is an m-plane. Alternatively, the side surface is a surface close to the m-plane. The m-plane is a nonpolar plane. Therefore, in the active layer 132, there is almost no decrease in light emission efficiency due to piezoelectric polarization.

2-1. Structure of Columnar Semiconductor

The columnar n-type semiconductor 131 is a semiconductor layer selectively growing in a columnar shape starting from the substrate 110 exposed to the opening 120a of the mask 120. The columnar n-type semiconductor 131 has a hexagonal columnar shape. A cross section perpendicular to an axial direction of the hexagonal columnar shape is a regular hexagon or a flat hexagon. Actually, the columnar n-type semiconductor 131 grows even slightly in a lateral direction. Therefore, the thickness of the columnar n-type semiconductor 131 is slightly larger than the opening width of the opening 120a of the mask 120. The columnar n-type semiconductor 131 is, for example, an n-type GaN layer.

The height of the columnar n-type semiconductors 131 is, for example, 0.25 μm or more and 5 μm or less. The diameter of the columnar n-type semiconductors 131 is, for example, 50 nm or more and 500 nm or less. Here, the diameter refers to a diameter of a circumscribed circle of a hexagon of the columnar n-type semiconductors 131. The interval between the columnar n-type semiconductors 131 (the distance between the centers of the adjacent columnar semiconductors 130) is, for example, 0.27 μm or more and 5 μm or less. These numerical values are examples, and numerical values other than those described above may be used.

The active layer 132 is formed along an outer periphery of the columnar n-type semiconductor 131 having a hexagonal columnar shape. Therefore, the active layer 132 has a hexagonal tubular shape. The active layer 132 includes, for example, one or more and five or less well layers, and barrier layers for sandwiching the well layers. The well layer of the active layer 132 is substantially perpendicular to a plate surface of the substrate 110. In this case, a top portion of the active layer 132 may cover a top portion of the columnar n-type semiconductor 131. The top portion of the active layer 132 may be substantially parallel to the plate surface of the substrate 110. For example, the well layer is an InGaN layer, and the barrier layer is an AlGaInN layer.

The tubular p-type semiconductor 133 is formed along an outer periphery of the active layer 132 having a hexagonal tubular shape. Therefore, the tubular p-type semiconductor 133 has a hexagonal tubular shape. The tubular p-type semiconductor 133 is in direct contact with the active layer 132, but may not be in direct contact with the columnar n-type semiconductor 131. The tubular p-type semiconductor 133 is, for example, a p-type GaN layer. An electron barrier layer may be provided between the active layer 132 and the tubular p-type semiconductor 133. The electron barrier layer is a p-type semiconductor having a band gap larger than that of the tubular p-type semiconductor 133. The electron barrier layer is, for example, p-AlGaInN. The electron barrier layer is provided, so that electrons can be efficiently injected into the active layer 132, and the light emission efficiency can be improved.

The tunnel junction layer 134 is formed along an outer periphery of the tubular p-type semiconductor 133. Therefore, the tunnel junction layer 134 has a hexagonal tubular shape. The tunnel junction layer 134 includes a p+ layer 135 and an n+ layer 136. The p+ layer 135 is located between the tubular p-type semiconductor 133 and the n+ layer 136. The p+ layer 135 is a layer having a high concentration of p-type impurities, and is, for example, p-GaN. The concentration of Mg in the p+ layer 135 is, for example, 2×10²⁰ cm⁻³. The n+ layer 136 is a layer having a high concentration of n-type impurities, and is, for example, n-GaN. The concentration of Si in the n+ layer 136 is, for example, 4×10²⁰ cm⁻³. The tunnel junction layer 134 is provided, and the buried layer 140 is made of n-GaN, so that conduction can be achieved.

Note that the tunnel junction layer 134 may be omitted and the buried layer 140 may be a structure made of p-GaN. However, when n-GaN is used as in the first embodiment, the conductivity can be improved as compared with the case where p-GaN is used.

2-2. Cross-sectional Shape

FIG. 4 is a first cross-sectional view showing a cross section taken along a line IV-IV in FIG. 3. FIG. 4 shows a cross section of the columnar semiconductor 130 parallel to the plate surface of the substrate 110. As shown in FIG. 4, the shape of the cross section of the columnar semiconductor 130 perpendicular to the axial direction is a regular hexagon. The columnar n-type semiconductor 131, the active layer 132, the tubular p-type semiconductor 133, and the tunnel junction layer 134 are arranged from an inner side of the columnar semiconductor 130 having a hexagonal columnar shape. The shape of the cross section of the columnar semiconductor 130 perpendicular to the axial direction does not need to be a regular hexagon, and may be a flat hexagon.

### 3. Dislocation Density of Buried Layer

The dislocation density on the surface of the buried layer 140 is not uniform and has a distribution. On the surface of the buried layer, threading dislocations are distributed with the same periodicity as the arrangement of the columnar semiconductors 130, and the dislocation density of an upper region (hereinafter, referred to as region A) of the columnar semiconductors 130 is different from the dislocation density of another region (hereinafter, referred to as region B) (see FIG. 5). The dislocation density of the region A is about 2 to 2000 times higher than the dislocation density of the region B. The dislocation density of the region A is, for example, 1×10⁹ to 2×10¹⁰ cm⁻², and the dislocation density of the region B is, for example, 1×10⁷ to 5×10⁸ cm⁻².

The reason why the dislocation density on the surface of the buried layer 140 has such a distribution is as follows. The active layer 132 formed at the top portion of the columnar semiconductor 130 (the region corresponding to the c-plane GaN) tends to have low crystal quality. Therefore, threading dislocations are formed at a higher density from the top portion of the columnar semiconductor 130. On the other hand, the threading dislocations in the region B are formed when the buried layers 140 grown from the adjacent columnar semiconductors 130 are combined, or are caused by the threading dislocations generated in the active layer 132 formed on the m-plane of the columnar semiconductors 130. In the process in which the buried layer 140 grows in the lateral direction and is flattened, the dislocations generated in the active layer 132 on the m-plane also propagate in the lateral direction, and there is a high possibility that the dislocations are eliminated with each other. Alternatively, there is a possibility that dislocations generated by lattice mismatch and dislocations propagating in the lateral direction are originally small. Therefore, the density of the threading dislocations in the region B is lower than that in the region A.

### 4. Method for Producing Semiconductor Light Emitting device 4-1. Substrate Preparing Step

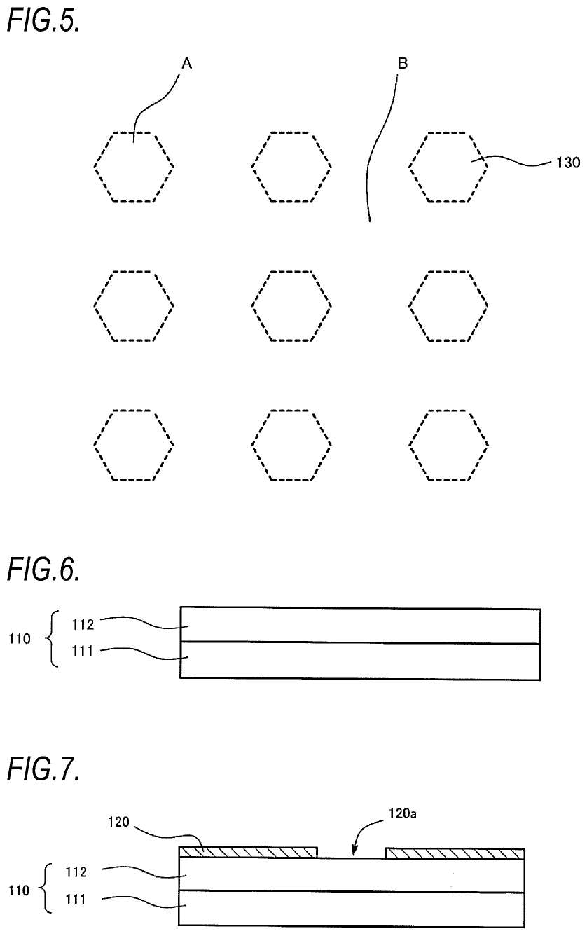

As shown in FIG. 6, a growth substrate 111 is prepared. Then, the n-type semiconductor layer 112 is laminated on the growth substrate 111 according to the MOCVD method. Hereinafter, the MOCVD method is used for forming all the semiconductor layers.

4-2. Mask Forming Step

As shown in FIG. 7, the mask 120 is formed on the n-type semiconductor layer 112. FIG. 7 depicts the opening 120a formed in an opening forming step to be described later.

4-3. Opening Forming Step

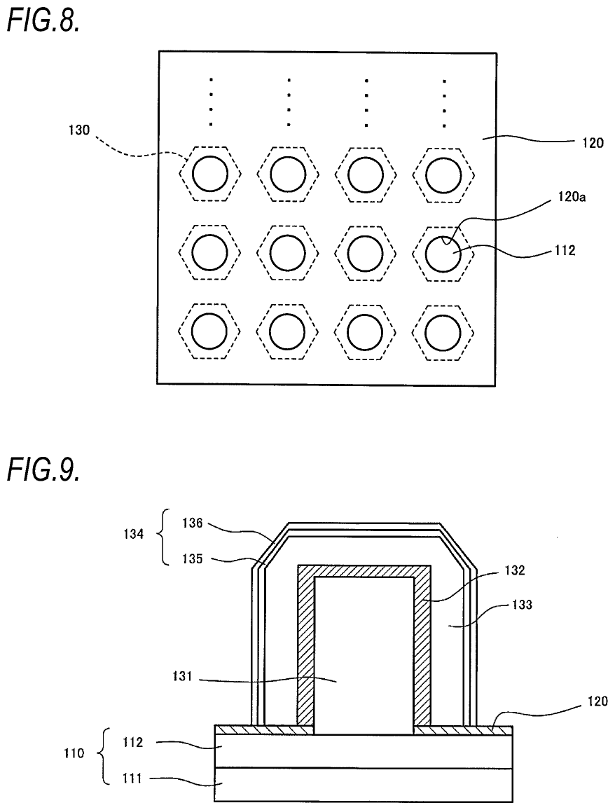

As shown in FIG. 7, a plurality of openings 120a for allowing the n-type semiconductor layer 112 to be exposed are formed in the mask 120. For example, nanoimprint is used for the patterning of the mask 120. The diameter of the opening 120a is, for example, 100 to 500 nm. FIG. 8 shows an arrangement of the openings 120a of the mask 120. FIG. 8 is a view of the substrate 110 viewed from a direction perpendicular to the plate surface of the substrate 110. In FIG. 8, for reference, a shape of the columnar semiconductor 130 is depicted by a broken line. As shown in FIG. 8, the openings 120a of the mask 120 are circular and are arranged in a square lattice shape.

The shape of the columnar semiconductor 130 can be controlled by changing the shape of the openings 120a of the mask 120. In a case where the shape of the opening 120a is circular, the columnar semiconductor 130 having a cross-sectional shape close to a regular hexagon can be formed. In a case where the shape of the opening 120a is an oval shape, a columnar semiconductor 130 having a cross-sectional shape close to a flat shape can be formed.

4-4. Columnar Semiconductor Forming Step

As shown in FIG. 9, the columnar n-type semiconductor 131 having a hexagonal columnar shape selectively grows starting from the n-type semiconductor layer 112 exposed under the opening 120a of the mask 120. For this purpose, a known selective growth technique may be used. In a case where the semiconductor layer selectively grows in this manner, the m-plane is easily exposed as a facet.

As described above, since the opening 120a of the mask 120 has a circular shape, the columnar n-type semiconductor 131 having a hexagonal columnar shape whose cross section is close to a regular hexagon grows.

Next, the active layer 132 is formed around the columnar n-type semiconductor 131. The active layer 132 is formed on a side surface of the columnar n-type semiconductor 131 having a shape whose cross section is close to a regular hexagon. The active layer 132 is also formed on the top portion of the columnar n-type semiconductor 131.

Next, the tubular p-type semiconductor 133 for covering the outer periphery of the active layer 132 is formed on the active layer 132. The tubular p-type semiconductor 133 has a hexagonal tubular shape. The tubular p-type semiconductor 133 is formed on a side surface of the active layer 132. The tubular p-type semiconductor 133 is also formed on the top portion of the active layer 132.

Next, the p+ layer 135 for covering the tubular p-type semiconductor 133 is formed on the tubular p-type semiconductor 133, and the n+ layer 136 for covering the p+ layer 135 is further formed. Accordingly, the tunnel junction layer 134 is formed. The tunnel junction layer 134 is formed on a side surface of the tubular p-type semiconductor 133. The tunnel junction layer 134 is also formed on a top portion of the tubular p-type semiconductor 133. In this way, the columnar semiconductor 130 is formed.

4-5. Buried Layer Forming Step

Next, a gap between one columnar semiconductor 130 and the other one columnar semiconductor 130 is buried with the buried layer 140. The buried layer forming step includes three steps of a facet structure forming step, a c-plane forming step, and a flattening step.

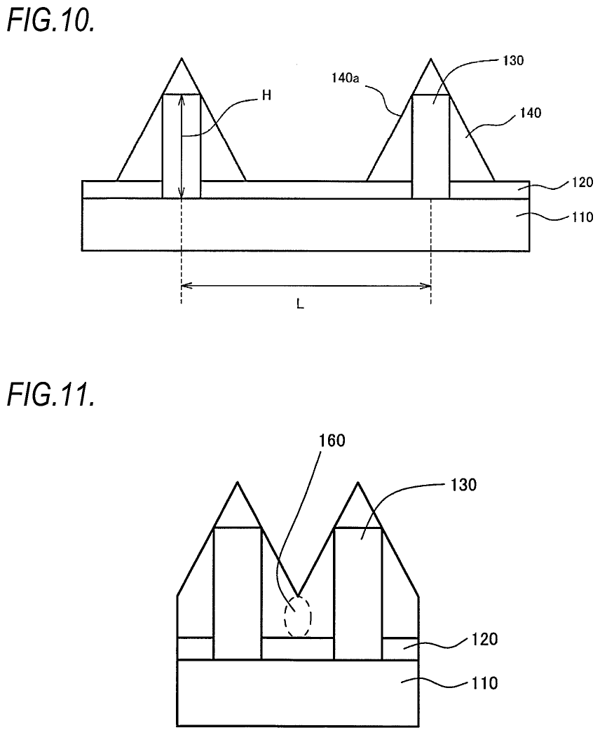

First, in the facet structure forming step as shown in FIG. 10, the buried layer 140 grows so as to form a periodic facet structure that matches an arrangement pattern of the columnar semiconductors 130. That is, a surface of the buried layer 140 grows such that an inclined surface 140a becomes dominant, and a surface parallel or perpendicular to the substrate 110 grows so as not to appear as much as possible. A shape of the buried layer 140 at this stage is, for example, a shape in which pyramid shapes are continuously connected in the same pattern as the arrangement of the columnar semiconductors 130, and the columnar semiconductors 130 are included in the pyramid. The inclined surface 140a is a {10 −1x} plane (here, x is a natural number of 1 or more), which is a plane obtained by inclining a {10 −10} plane (m-plane), and is mainly a {10 −11} plane.

Such a facet structure can be formed by controlling growth conditions. For example, the facet structure along the periodic structure can be formed by setting the growth temperature to 900 to 950° C., setting the growth pressure to 10 to 100 kPa, setting V/III to 1000 to 5000, and setting the growth rate to 5 to 50 nm/min.

The facet structure is, for example, a structure in which a proportion of the area of the {0001} plane of the buried layer 140 to the total area of the surface of the buried layer 140 when the surface of the buried layer 140 is projected onto the {0001} plane is 30% or less. The {0001} plane is a (0001) plane (+c-plane) or a (000 −1) plane (−c-plane).

In the facet structure forming step, in a case where the height H of the columnar semiconductors 130 is large or in a case where the distance L between the columnar semiconductors 130 (the distance between a center of one columnar semiconductor 130 and a center of the other adjacent columnar semiconductor 130) is small, raw material gas hardly reaches a lower portion sufficiently as the buried layer 140 grows, and a void 160 of the buried layer 140 may be generated in the region. In particular, in a stage immediately after the formation of the facet structure, in a case where an inclined surface 140a of one facet structure and an inclined surface 140a of the adjacent other facet structure intersect with each other above the mask 120, the void 160 is likely to be generated at the intersection (see FIG. 11). Therefore, it is preferable to set the height H and the distance L to satisfy the following expression.

1.06×H−0.25≤L≤1.06×H+2

When the height H and the distance L are set so as to satisfy this expression, an inclined surface of one facet structure and an inclined surface of the adjacent other facet structure do not intersect with each other above the mask 120 or intersect with each other in the vicinity of the surface as shown in FIG. 10 in a stage immediately after the formation of the facet structure. Accordingly, the generation of the void 160 can be prevented. This expression is derived by calculating, based on an angle of about 62° formed by a {10 −11} plane, which is an inclined surface mainly formed, and a (0001) plane (c-plane), a case where the above condition is satisfied. The lower limit in the expression is determined in consideration of a range in which the void 160 is allowed to be small even when the void 160 is formed. In addition, the upper limit is set in consideration of the ease of burying between the columnar semiconductors 130. That is, when the distance between the columnar semiconductors 130 is large, the volume to be buried increases, and flattening becomes difficult. Therefore, the distance between the columnar semiconductors 130 that facilitates flattening is taken into consideration. It is more preferable to set the height H and the distance L to satisfy the following expression.

1.06×H−0.15≤L≤1.06×H+1.5

It is still more preferable to set the height H and the distance L to satisfy the following expression.

1.06×H≤L≤1.06×H+1

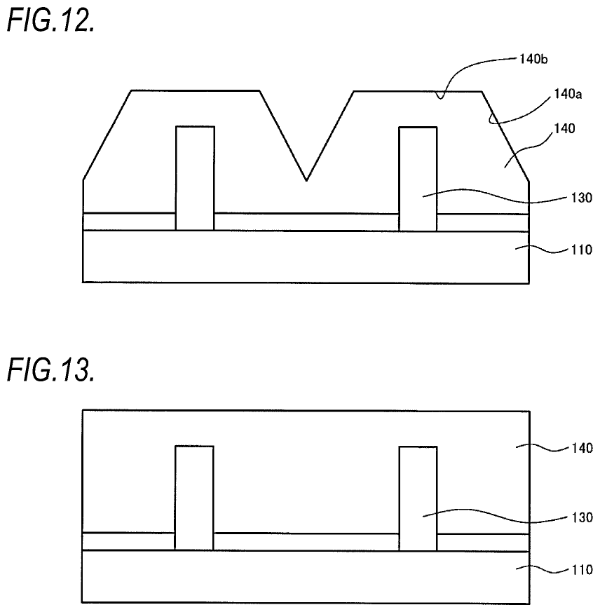

When the adjacent facet structures start to come into contact with each other, the processing shifts to the next c-plane forming step. In the c-plane forming step, the buried layer 140 grows such that the {0001} plane (upper surface 140b) is formed in a region of the buried layer 140 corresponding to the upper portion of the columnar semiconductor 130 as shown in FIG. 12. The shape of the buried layer 140 at this stage is, for example, a shape in which truncated pyramids are continuously connected in the same pattern as the arrangement of the columnar semiconductors 130, and the columnar semiconductors 130 are included in the truncated pyramids. Since the buried layer 140 grows while maintaining the periodic structure including the inclined surface 140a formed in the facet structure forming step, the space between the columnar semiconductors 130 can be buried with no gap without generating a void in the buried layer 140. When the burying progresses randomly in the plane without maintaining the periodic structure, a void is generated or a surface having severe unevenness is formed. When the growth mode is not uniform in the plane, such a periodic structure cannot be maintained.

Such a {0001} plane can be formed by controlling growth conditions. For example, the c-plane can be formed by setting the growth temperature to 950 to 1050° C., setting the growth pressure to 10 to 100 kPa, setting the V/III to 1000 to 5000, and setting the growth rate to 5 to 50 nm/min. The processing shifts from the facet structure forming step to the c-plane forming step by changing only the growth temperature. When the processing shifts from the facet structure forming step to the c-plane forming step, the growth temperature is preferably increased stepwise rather than being increased continuously. By changing the growth mode in a stepwise manner, the growth proceeds while maintaining the periodic structure, voids can be further prevented, burying becomes easier, and flatness becomes good.

The shift from the facet structure forming step to the c-plane forming step may be performed, for example, when the proportion of the area of the {0001} plane of the buried layer 140 to the total area of the surface of the buried layer 140 at the time of projecting the surface of the buried layer 140 onto the {0001} plane becomes larger than 30%.

When the area of the {0001} plane becomes sufficiently large, the processing shifts to the next flattening step. In the flattening step, the lateral growth of the buried layer 140 is promoted, and the c-plane formed in the c-plane forming step is widened to flatten the surface of the buried layer 140 as shown in FIG. 13. The facet structures are combined at the same time while the periodic structure is maintained, and the buried layer 140 grows to bury the space between the columnar semiconductors 130. Since the buried layer 140 grows while maintaining the periodic structure including the inclined surface, the space between the columnar semiconductors 130 can be buried with no gap without generating a void in the buried layer 140. The facet structures are combined with each other at the same time, and therefore, the surface of the buried layer 140 can be uniformly flattened.

The shift from the c-plane forming step to the flattening step may be performed, for example, when the proportion of the area of the {0001} plane of the buried layer 140 to the total area of the surface of the buried layer 140 at the time of projecting the surface of the buried layer 140 onto the {0001} plane becomes 70% or more.

Lattice mismatch may occur due to combination of adjacent facet structures. In the process in which the buried layer 140 grows in the lateral direction and is flattened, dislocations also propagate in the lateral direction, and there is a high probability that the dislocations are eliminated with each other. Alternatively, there is a possibility that dislocations generated by lattice mismatch and dislocations propagating in the lateral direction are originally small. Therefore, regarding the dislocation density of the surface of the buried layer 140, the dislocation density of the other region B is lower than that of the upper region A of the columnar semiconductor 130.

Since the buried layer 140 grows in the lateral direction toward a face center (a center of the square lattice) in the arrangement of the square lattice of the columnar semiconductor 130, the threading dislocations also propagate toward the face center, and the threading dislocations remaining without pair elimination gather at the surface center. Therefore, threading dislocations on the surface of the buried layer 140 are likely to be distributed on the face center of the square lattice. Similarly, in the case of the arrangement of the triangular lattice, threading dislocations are likely to be distributed in a face center of the triangular lattice.

The thickness (the thickest portion) of the buried layer 140 required for the flattening of the buried layer 140 depends on the height H of the columnar semiconductors 130, and is, for example, 1 to 5 μm. The buried layer 140 is formed as described above.

The buried layer 140 can be flattened by controlling the growth conditions. For example, the c-plane can be formed by setting the growth temperature to 1000 to 1100° C., setting the growth pressure to 10 to 100 kPa, setting the V/III to 1000 to 5000, and setting the growth rate to 5 to 50 nm/min. The processing shifts from the c-plane forming step to the flattening step by changing only the growth temperature. When the processing shifts from the c-plane forming step to the flattening step, the growth temperature is preferably increased stepwise rather than being increased continuously. By changing the growth mode in a stepwise manner, the growth proceeds while maintaining the periodic structure, voids can be further prevented, burying becomes easier, and flatness becomes good.

Note that the processing may directly shift from the facet structure forming step to the flattening step with the c-plane forming step being omitted.

Although the void 160 may be formed in the buried layer 140, the height of the void 160 formed between the columnar semiconductors 130 may be preferably 30% or less, and more preferably 20% or less of the height of the columnar semiconductors 130 from a surface of the mask 120. In the case of the laser diode, there is little adverse effect on the formation of a standing wave even if the void 160 as described above is formed. In the LED, the light extraction efficiency can also be controlled by uniformly controlling the formation of the void 160.

As described above, the space between the columnar semiconductors 130 can be buried without generating a void, and the buried layer 140 having a flat surface can be formed in the first embodiment even at a temperature of 1100° C. or lower, which is lower than the conventional temperature. In the past, the buried layer 140 is formed at a temperature higher than 1100° C. to perform flattening without voids, and the active layer 132 is heat-damaged. However, a low growth temperature of 1100° C. or lower is raised in the first embodiment, and thus, the thermal damage to the active layer 132 can be prevented more than before on average.

4-6. Electrode Forming Step

Next, the cathode electrode N1 is formed on the back surface of the substrate 110. In addition, the anode electrode P1 is formed on the buried layer 140. Thus, the semiconductor light emitting device 100 of the first embodiment shown in FIGS. 1 and 2 is produced.

4-7. Other Steps

A heat treatment step, a step of forming a passivation film or the like on a surface of a semiconductor layer, or other steps may be performed.

### 5. Effects of First Embodiment

In the first embodiment, the space between the columnar semiconductors 130 can be buried flatly with the buried layer 140 with no gap, and thermal damage to the active layer 132 can also be prevented.

### 6. Modification

6-1. Device Structure of Semiconductor Light Emitting Device

In the present embodiment, the device structure of the semiconductor light emitting device may be a vertical structure in which the cathode electrode N1 is provided on the back surface of the substrate 110 and conduction is made perpendicular to the main surface of the substrate 110, and may be a flip-chip or face-up device structure in which the cathode electrode N1 is provided on the same side as the anode electrode P1. In this case, the n-type semiconductor layer 112 may be exposed by performing etching from an upper surface side of the buried layer 140, and the cathode electrode N1 may be formed on the exposed n-type semiconductor layer 112.

6-2. Composition of Columnar Semiconductor

In the present embodiment, the columnar n-type semiconductor 131 is an n-type GaN layer, the well layer is an InGaN layer, the barrier layer is an AlGaInN layer, and the tubular p-type semiconductor 133 is a p-type GaN layer. These are merely examples, and other Group III nitride semiconductors may be used. In addition, other semiconductors may be used.

6-3. Surface Layer

A plurality of protruding portions may be provided on the surface of the buried layer 140 to extract light. A surface layer may be provided on the buried layer 140, or a plurality of protruding portions may be provided on the surface layer. The surface layer is, for example, an n-GaN layer having a doping amount different from that of the buried layer 140. The material of the surface layer may be a transparent conductive oxide such as ITO or

IZO. The arrangement of the protruding portions is, for example, a honeycomb shape or a square lattice shape. In addition, a recessed portion may be provided instead of the protruding portion.

6-4. Composition of Buried Layer

In the present embodiment, the material of the buried layer 140 is an n-GaN layer. However, an n-AlGaN layer may be used as the buried layer 140 instead of the n-GaN layer. n-GaN and n-AlGaN may be combined. In the case of a laser diode, optical confinement can be enhanced by a difference in refractive index when n-AlGaN is formed on n-GaN.

6-5. Dopant for Buried Layer

In the present embodiment, Si is used as an n-type dopant of the buried layer 140, but the n-type dopant is not limited to Si. In this case, the effect is large in a case where the buried layer 140 is an n-type layer doped with Si in the present embodiment. Si acts as a surfactant for promoting the vertical growth, and when the vertical growth is strong, voids are easily generated in the buried layer 140 and the surface is likely to be roughened. Therefore, as described in the present embodiment, the growth mode is controlled in three stages of the facet structure forming step, the c-plane forming step, and the flattening step, and thus, even in the case of Si doping, it is possible to stably obtain the buried layer 140 in which voids are prevented and surface roughness is small. In a case where Mg is used as the dopant, the lateral growth is promoted. Therefore, it becomes easier to obtain a flatter buried layer 140.

6-6. Current blocking layer of Columnar Semiconductor

It is preferable to promote current injection from the side surface of the columnar semiconductor 130. For example, a transparent insulating film is provided on the top portion of the columnar semiconductor 130. Accordingly, the current flowing to the top portion of the columnar semiconductor 130 is blocked, and the current can be favorably injected from the side surface of the columnar semiconductor 130.

6-7. Concave-convex Processed Substrate

In a case where the semiconductor device is used as LED, the growth substrate 111 of the substrate 110 may be subjected to concave-convex processing. That is, the growth substrate 111 has a concave-convex shape portion in which concave portions and convex portions are periodically arranged on the surface on the semiconductor layer side. Examples of the concave-convex shape include a conical shape and a hemispherical shape. These concave-convex shapes may be arranged, for example, in a square lattice shape or a honeycomb shape. Accordingly, the light extraction efficiency is further improved.

6-8. Application to Other Semiconductor Devices

Although the first embodiment relates to a semiconductor light emitting device, the present invention can also be applied to a device other than the light emitting device as long as the device has a structure including a plurality of columnar semiconductors that are arranged periodically and a buried layer that is buried between the columnar semiconductors.

For example, the present invention can also be applied to a light receiving device such as a solar cell.

6-9. Combination

The above modifications may be freely combined.

### 7. Experimental Results

Various experimental results relating to the semiconductor light emitting device 100 of the first embodiment will be described.

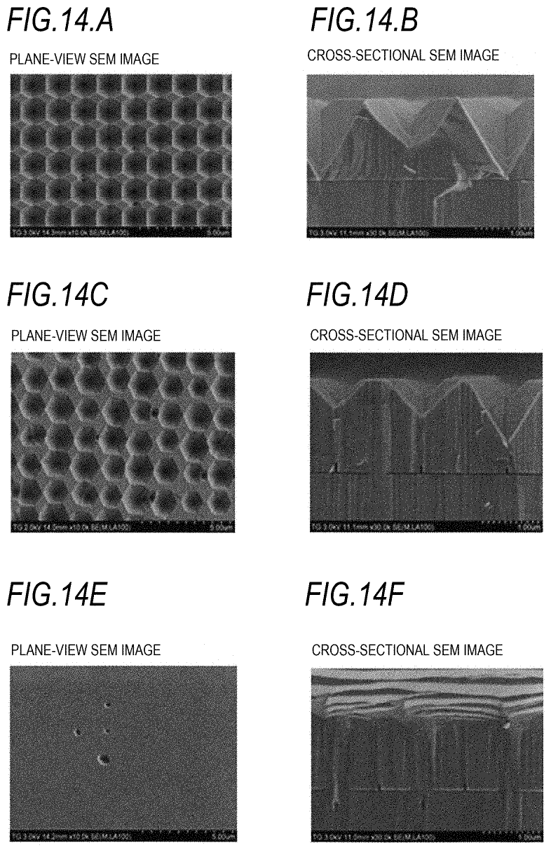

FIGS. 14A to 14F are SEM images obtained by imaging shapes of the buried layer 140 in the step of forming the buried layer 140. FIG. 14A is a plane-view SEM image taken at the stage of the facet structure forming step, and FIG. 14B is a cross-sectional SEM image. FIG. 14C is a plane-view SEM image taken at the stage of the c-plane forming step, and FIG. 14D is a cross-sectional SEM image. FIG. 14E is a plane-view SEM image taken after the flattening step, and FIG. 14F is a cross-sectional SEM image.

As shown in FIGS. 14A and 14B, it can be seen that the facet structure is periodically formed in the same arrangement pattern as the square lattice arrangement of the columnar semiconductors 130 at the stage of the facet structure forming step. As shown in FIGS. 14C and 14D, it can be seen that the upper c-plane region of the columnar semiconductors 130 is enlarged at the stage of the c-plane forming step. In addition, as shown in FIGS. 14E and 14F, it can be seen that although there is an unflattened region in a very small portion, most of the regions can be flattened, and it can be seen that the generation of voids in the buried layer 140 can be prevented.

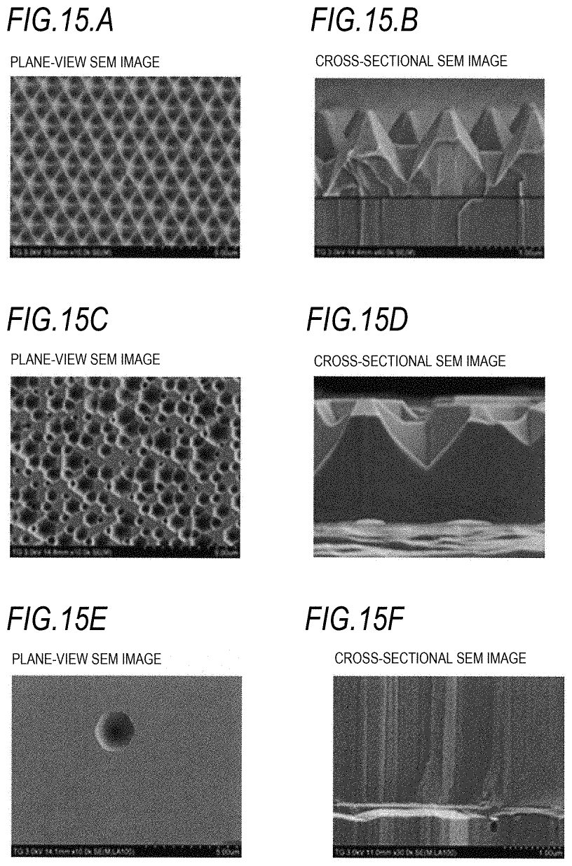

FIGS. 15A to 15F are SEM images obtained by imaging the shapes of the buried layer 140 in a case where the arrangement pattern of the columnar semiconductors 130 is changed from a square lattice to a regular triangular lattice. FIG. 15A is a plane-view SEM image taken at the stage of the facet structure forming step, and FIG. 15B is a cross-sectional SEM image. FIG. 15C is a plane-view SEM image taken at the stage of the c-plane forming step, and FIG. 15D is a cross-sectional SEM image. FIG. 15E is a plane-view SEM image taken after the flattening step, and FIG. 15F is a cross-sectional SEM image.

As shown in FIGS. 15A and 15B, it can be seen that a facet structure is periodically formed in the same arrangement pattern as the regular triangular lattice arrangement of the columnar semiconductors 130 at the stage of the facet structure forming step. As shown in FIGS. 15C and 15D, it can be seen that the upper c-plane region of the columnar semiconductor 130 is enlarged at the stage of the c-plane forming step. In addition, as shown in FIGS. 15E and 15F, it can be seen that although there is an unflattened region in a very small portion, most of the region can be flattened, and it can be seen that the generation of voids in the buried layer 140 can be prevented.

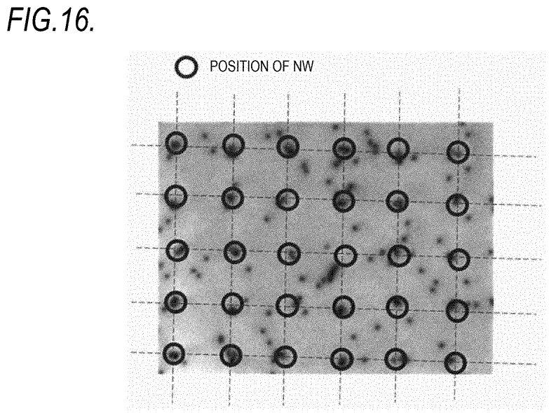

FIG. 16 is a CL image obtained by imaging the surface of the buried layer 140 after the formation of the buried layer 140. In FIG. 16, a region indicated by a circle is an upper region of the opening 120a of the mask 120, and is an upper region of the columnar semiconductor 130. In FIG. 16, dark points indicate threading dislocations.

As shown in FIG. 16, it can be seen that a region of the buried layer 140 where the columnar semiconductors 130 are located has a dislocation density higher than that of other regions.

The semiconductor device in the present specification can be used as a light emitting device such as a laser diode or an LED, or a light receiving device such as a solar cell.

What is claimed is:

1. A method for producing a semiconductor device, which includes a plurality of columnar semiconductors that are periodically arranged and a buried layer made of a semiconductor that is buried between the columnar semiconductors, the method comprising a step of forming the buried layer that includes:
a facet structure forming step of causing the buried layer to grow to form a periodic facet structure that matches an arrangement pattern of the columnar semiconductors; and
a flattening step of flattening the buried layer by causing the buried layer to grow in a lateral direction by means of causing the buried layer to grow at a temperature higher than that in the facet structure forming step.

2. The method for producing a semiconductor device according to claim 1,
wherein a growth temperature of the buried layer in the facet structure forming step is 900 to 950° C., and
a growth temperature of the buried layer in the flattening step is 1000 to 1100° C.

3. The method for producing a semiconductor device according to claim 1, further comprising, after the facet structure forming step and before the flattening step, a c-plane forming step of forming a {0001} plane in a region of the buried layer corresponding to an upper portion of the columnar semiconductor by causing the buried layer to grow at a temperature higher than that in the facet structure forming step and lower than that in the flattening step.

4. The method for producing a semiconductor device according to claim 3, wherein a growth temperature of the buried layer in the c-plane forming step is 950 to 1050° C.

5. The method for producing a semiconductor device according to claim 1, wherein, in the facet structure, a proportion of an area of the {0001} plane of the buried layer to a total area of the surface of the buried layer when the surface of the buried layer is projected onto the {0001} plane is 30% or less.

6. The method for producing a semiconductor device according to claim 1, wherein, in the step of forming the buried layer, a growth pressure of the buried layer is 10 to 100 kPa, V/III is 1000 to 5000, and a growth rate is 5 to 50 nm/min.

7. The method for producing a semiconductor device according to claim 1, wherein the columnar semiconductors are arranged in a square lattice shape or a regular triangular lattice shape, H is a height of the columnar semiconductors, L is a distance between the columnar semiconductors, and H and L are set to satisfy 1.06×H−0.25≤L≤1.06×H+2.

8. A semiconductor device comprising:
a plurality of columnar semiconductors that are periodically arranged; and
a buried layer that is buried between the columnar semiconductors,
wherein, on the surface of the buried layer, threading dislocations are distributed with the same periodicity as arrangement of the columnar semiconductors, and a dislocation density in an upper region of the columnar semiconductors is different from a dislocation density in another region.
